(19) United States
(12) Patent Application Publication
(10) Pub. No.: US 2011/0192343 A1
(43) Pub. Date: Aug. 11, 2011

(54) METHOD OF MANUFACTURING A STRUCTURE COMPRISING A SUBSTRATE AND A LAYER DEPOSITED ON ONE OF ITS FACES

(76) Inventors: Hocine Abir, Le Pont De Claix (FR); Robert Langer, Grenoble (FR)

(21) Appl. No.: 12/672,797

(22) PCT Filed: Sep. 23, 2008
(86) PCT No.: PCT/EP08/62670

§ 371 Date: Feb. 9, 2010

(30) Foreign Application Priority Data
Sep. 27, 2007 (FR) 07 57891

(51) Int. Cl. C30B 23/02; B05D 3/12

(52) U.S. Cl. 117/106; 427/58; 427/162

(57) ABSTRACT

A method for manufacturing an electronic, optic, optoelectronic or photovoltaic structure of a substrate having a thin layer on one face thereof, by forming an embrittled substrate having first and second faces and an embrittlement zone therebetween, the embrittlement zone defining the substrate and a remainder; depositing a thin layer of material on both the first and second faces of the embrittled substrate; and cleaving the embrittled substrate at the embrittlement zone to obtain the structure having the thin layer of deposited material on one face and one face that is exposed.

### FIELD OF THE INVENTION

The present invention relates to a method of manufacture of a structure for electronics, optics, optoelectronics or photovoltaics, the structure comprising a substrate and a layer formed by depositing a material on one of the sides of the substrate.

### RELATED BACKGROUND ART

The state of the art shows that it is possible to select the side of a substrate on which a thin layer will be deposited according to a technology adapted such as PECVD (acronym for “Plasma-Enhanced Chemical Vapour Deposition). Nevertheless, the process is complex, it can lead to metallic contaminations and the deposited layer can delaminate.

The use of a non-selective technique results in a deposit on both faces of the substrate. It is then possible to eliminate the layer deposited on the face on which it is not desired. For this purpose, one can bond, for example, the layer which one wishes to conserve on another material, so as to protect it, then to perform an etching in order to eliminate the layer on the non-protected side. However, according to the nature of this layer (notably, if it is in SiN, AlN or diamond), its withdrawal is sometimes very difficult and non-selective compared with the material of the substrate.

It is also possible to use an RIE etching (acronym for “Reactive Ion Etching”) the description of which is found in the work; “Silicon Processing for the VLSI Era, Vol. 1: Process Technology” by Stanley Wolf and Richard N. Tauber, Lattice Press; 2^{nd} edition (Nov. 1, 1999), ISBN-10: 0961672161 in Chapter “14, Dry Etching for VLSI”. This dry etching assisted by plasma permits the selection of the face to clean without having to protect the other face, but its efficiency depends on the material to remove. Moreover, this relatively difficult technology requires the use of very toxic gases and pollutants such as NF₃ or SF₆. It involves, therefore, specialized operating conditions, in particular a special confinement

A particular example of this problem is encountered during the formation of a layer of polycrystalline silicon on the rear face of a SopSiC (acronym of “Silicon on Polycrystalline SiC”) or a SiCopSiC (acronym of “Silicon Carbide On Polycrystalline SiC”) substrate.

The SopSiC substrate being principally transparent to infrared radiation, it is not possible to heat it sufficiently through the rear face of this substrate in order to attain a temperature suited for the realization, on the front face, of a molecular beam epitaxy (MBE).

A layer of polycrystalline silicon deposited on the rear face, which absorbs the infrared radiation, can be heated to a high temperature and allows thereby the heating of the SopSiC substrate by conduction so as to reach the temperatures necessary to achieve epitaxy. In this respect, one might consult the publications, U.S. Pat. No. 5,296,385, US 2004/0152312, EP 0 449 524, WO 2006/082467 and FR 07 54172.

Currently, the method of realization consists in depositing polycrystalline silicon without selection of the face on the SopSiC substrate i.e., on both faces of the latter, then to perform an etching to eliminate the layer formed on the face where it is not desired.

Referring to FIG. 1A, an embrittlement zone 510 delimiting a layer 500 is formed by implantation in a substrate 520 in monocrystalline silicon.

Referring to FIG. 1B, a structure 100 designated as SopSiC is formed by bonding, thanks to a bonding layer 300 in SiO₂, the substrate 520 in monocrystalline silicon on a support 400 in polycrystalline SiC (also noted as p-SiC) and by transferring the layer 500 on the support 400.

Referring to FIG. 1C, the bonding of the structure 100 is stabilized by an annealing under an atmosphere of water vapour at a temperature of about 800 to 1200° C., which contributes to the formation of layers 110 and 120 of SiO₂ on both sides of the structure 100 by thermal oxidation of silicon and SiC, i.e., by consumption of silicon on the surface of the layers 400 and 500.

Referring to FIG. 1D, next a deposit of layers 200 of polycrystalline silicon (also noted p-Si) is performed without distinction of face on the structure obtained previously. For this purpose, a LPCVD technique (Low Pressure Chemical Vapor Deposition) can be used at a temperature of 620° C.

Referring to FIG. 1E, the layer 200 of p-Si situated at the side of the layer in monocrystalline silicon 500 is removed from the SopSiC structure by an RIE etching.

Referring to FIG. 1F, the layer 110 of SiO₂ situated at the side of the monocrystalline silicon layer 500 is removed from the SopSiC structure by the action of a solution of HF which dissolves selectively the SiO₂ and leaves the silicon intact. Finally, the surface of the layer 500 in monocrystalline silicon is cleaned to prepare it for the epitaxy by MBE.

It is understood that this method comprises a large number of steps and utilizes a complex and costly technology to implement in order to carry out the selective etching.

Moreover, a layer 120 in SiO₂ which is a strong thermal insulator is formed between the rear layer 200 in silicon polycrystalline and the layer 400 in SiC polycrystalline, which decreases the efficiency of the heating by this rear layer. The suppression of this layer 120 of SiO₂ would necessitate a supplemental etching step which is very costly to implement.

One of the objects of the invention is therefore to propose a method of manufacturing a structure in which a layer of material is deposited on only one face of a substrate using a non-selective deposition technique which is simple and low in cost to implement which does not cost much to implement, and avoids resorting to an etching of the RIE type.

### BRIEF DESCRIPTION OF THE INVENTION

According to the invention, it is proposed to provide a method of manufacturing a structure for use in electronics, optics, optoelectronics or photovoltaics, the structure comprising a substrate and a layer formed by the depositing of a material on one of the faces of the substrate, the method being characterized in that it comprises the steps of:
forming an embrittled substrate comprising an embritlement zone defining, on the one hand, the said substrate and, on the other hand, a remainder,
depositing of a layer of said material on each of the two faces of the embrittled substrate,
cleavage of the embrittled substrate,
   so as to form said structure in which a face of the substrate is covered by the layer of material deposited while its other side is exposed. By exposed is meant in this text the fact that said face of the substrate is not covered by a layer.

According to an embodiment, the thermal budget of cleavage is greater than the thermal budget provided by the deposition. The depositing step is therefore performed before the cleavage step.

According to a second embodiment, the thermal budget of cleavage is less than the thermal budget provided by the deposition.

The cleavage step can therefore be performed during the deposition step. The embrittled substrate is preferably held such that the cleaved parts do not move apart from one another; in a manner particularly advantageous, it is held horizontal during the deposition step.

According to a preferred embodiment, the cleavage step is performed in the depositing chamber of the material of the layer.

According to a variant of the implementation of the invention, the method comprises the successive steps of:
deposition on both faces of the embrittled substrate of the material in amorphous form,
cleavage of the embrittled substrate,
annealing to a temperature suitable to cristallise the material.

According to other possible characteristics of the invention:
the embrittlement zone is formed by implantation of ionic species in the substrate;
the substrate is a composite substrate comprising a support substrate and a seed layer;
the substrate comprises one of the following materials: Al₂O₃, ZnO, the materials of group III/V and their ternary and quaternary alloys, Si, SiC, polycrystalline SIC, diamond, Ge and their alloys;
the material deposited is chosen among the following materials: amorphous Si, monocrystalline Si, polycrystalline Si, Ge, SiC, polycrystalline SiC, amorphous SiC, the materials of group III/V and their ternary and quaternary alloys, Al₂O₃, SiO₂, Sl₃N₄ and diamond;
the substrate is a composite structure of the type SopSiC or SiCopSIC and the layer of material deposited is in polycrystalline silicon;
the method comprises additionally the carrying out of a molecular beam epitaxy on the exposed face of the substrate of the structure thus formed.

### RIEF DESCRIPTION OF THE DRAWINGS

Other characteristics, objectives and advantages of the invention will appear more clearly from the reading of the description which follows, from the drawings attached on which:

FIGS. 1A to 1F illustrate the steps of a non-selective deposition method of the prior art,

FIGS. 2A to 2C illustrate the formation of the embrittlement zone in the source substrate;

FIGS. 3A and 3B illustrate the steps of a first embodiment of the invention

FIGS. 4A and 4B illustrate the steps of a second embodiment of the invention

FIGS. 5A to 5C illustrate the steps of a third embodiment of the invention,

FIG. 6 represents a structure obtained by the method according to the invention and the structure and the residual structure,

FIGS. 7A to 7H illustrate a first example of application of the invention of the deposition of a rear layer in p-Si on a SopSiC substrate, according to a first variant,

FIGS. 8A to 8D illustrate a second variant of application of the invention of the deposition of a rear layer in p-Si on a SopSiC substrate,

FIGS. 9A to 9D illustrate an example of application of the invention of the deposition of a rear layer in p-Si on a SiCopSIC substrate.

### DETAILED DESCRIPTION OF THE INVENTION

In a general manner, the invention comprises the manufacture of a substrate 12, which may be bulk or composite (i.e., comprising a plurality of layers of different materials), substrate 12 comprising an embrittlement zone 11 according to which the substrate 12 can be cleaved.

By “cleavage” or “fracture”, is meant the action of splitting a substrate in two layers according to a plane parallel to the surface of the initial substrate, allowing thereby their later removal or detachment: the two layers thereby formed are independent, but a phenomenon of capillarity or a suction effect can create a certain adherence between them. It is specified, therefore, that the step of removal is a step posterior to cleavage and is distinct from the latter. In the description which follows, when a cleaved substrate is mentioned, it must be understood that the two layers are still in contact with each other.

After the formation of the embrittlement zone, comes the deposition of material on the two faces of the embrittled substrate and the cleavage of the embrittled substrate.

According to the cases which will be detailed below, the step of cleavage can take place during or after the deposition step.

Finally, the steps of deposition and cleavage described above are followed by the removal of the two cleaved parts from substrate 12, so as to obtain a structure 1 formed from the part 10 of substrate 12, the face of which have undergone the implantation is exposed and the other face is covered by the deposited material. The exposed face can be prepared for a later use, for example, an epitaxy.

The different steps of the method according to the invention will now be described in detail.

The invention is applicable as well to a bulk substrate 10 as well as to a composite substrate, i.e., formed from at least two different layers of material, or from materials having different crystalline characteristics.

In the case of a bulk substrate, the face of this substrate is chosen which will not be subsequently covered by the deposited layer. The question of selection can be posed when the material of the substrate is polar or according to the later intended usage such as an epitaxy, for example. According to the roughness, for example, or the density or defects, the person skilled in the art would choose the one or the other of the faces of the substrate. In the following text below, the “front face” is called the face of the substrate which will have to stay exposed and “rear face” the face covered with deposited material.

In the case of an epitaxy on a composite substrate comprising a support substrate and a seed layer, the front face will be the free surface of the seed layer, in a material in general selected by its lattice parameter adapted to that of the material epitaxied.

The substrate 10 can be chosen among the following materials: Al₂O₃, ZnO, the materials of the group III/V (for example: GaAs, InP, InSb, GaSb, InN, GaN, AlN, p-AlN; P-BN, BN and their ternary and quaternary alloys such as InGaN, AlGaN, InAlGaN), or even from the materials of group IV such as Si, SiC, p-SiC, Ge and their alloys. Among the composite substrates, one could cite, for example, the substrates of the type SopSiC or SiCopSiC as being particularly well adapted for epitaxies of materials III/N binaries, ternaries, quaternaries such as GaN, AlN, AlGaN, and InGaN.

When substrate 10 is bulk, it is preferable to bond a substrate having the function of a stiffener on the face through which the implantation is performed, intended to be removed in order to facilitate its detachment.

The material deposited can be chosen among the following materials: Si amorphous, monocristalline or polycrystalline Si, amorphous SiC, mono or polycrystalline SiC, Ge, the materials of group III/V (InP, GaAs, AlN, p-AlN . . . ), Al₂O₃, SiO₂, Si₃N₄, diamond.

When the invention concerns substrates transparent to infrareds that are intented for use in MBE, the material deposited is chosen for absorbing the infrareds. Generally it is sought to obtain a deposited crystalline layer rather than an amorphous layer in order to guarantee a better adherence to the substrate during the later thermal treatments.

Preferably, the invention concerns substrates principally transparent to infrareds in order to realize epitaxies by MBE.

The materials of these substrates can be chosen, for example, among SiC, sapphire (Al₂O₃), GaN, AlN (monocristalline as well as polycrystalline), BN, ZnO, InSb or diamond. These materials form the support substrate in the case of a composite substrate 10.

In fact, even if the seed layer is formed in absorbing material, the assembly of the composite substrate 10 remains, in principle, transparent to infrareds. The material deposited on the face of the substrate 10 opposite to the face which will serve for the epitaxy will be then chosen among the materials absorbing infrared rays such as silicon (amorphous, monocristalline, polycrystalline), Ge, InP and GaAs.

Formation of the Embrittlement Zone

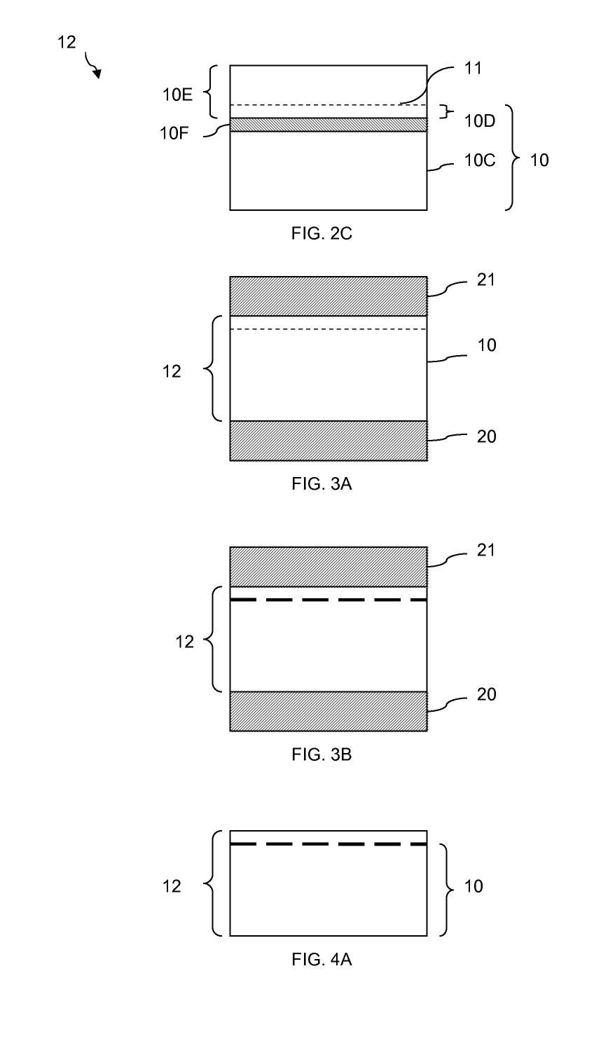

In reference to FIG. 2A, for a bulk substrate 12, after the preparation of the substrate on which one wishes to deposit a layer of material on one of the faces, a first step of the method consists in creating, in this substrate 12, an embrittlement zone 11 according to which the substrate could be cleaved.

Typically, the creation of this embrittlement zone is implemented by the implantation of ionic species in the substrate. The person skilled in the art can determine, according to the substrate to implant, the species implanted and the depth desired of the embrittlement zone, the conditions (dosage and energy) of the implantation.

The depth of the embrittlement zone defines the thickness of the substrate which will be removed with the layer of the material deposited on the face of the substrate intended to be kept exposed. Consequently, the implantation is preferably performed through the face of the substrate which will not have to be covered in the end by the deposited layer. The person of skill in the art will generally be interested in realizing an embrittlement zone of little depth so as to limit the loss of material of the initial substrate.

The embrittlement zone permits defining two layers in the substrate 12 (namely, substrate 10 which will belong to the final structure and a remainder), but these two layers are not independent at this stage.

In the scope of the invention, it is the application of an appropriate thermal budget which will allow their cleaving. By thermal budget, one understands the application of a determined temperature range during a defined time period.

The thermal budget of cleavage depends on the conditions of the implantation previously performed and on the materials considered. Typically, if one decreases the dose of implanted species, it will be necessary to apply a larger thermal budget to perform the cleavage. The determination of the thermal budget is within the skilled person's reach.

In the preceding case described and illustrated in FIG. 2A, the substrate 10 is bulk and the substrate 12 is equally so.

According to a variant of realisation, in order to obtain a bulk substrate 10, it can be advantageous, in reference to FIG. 2B, to form first a composite substrate 12 by bonding a stiffener 10B to a bulk substrate 10A on the face of the substrate which, in the end, will not have to be covered with the deposited layer.

In this case, the embrittlement zone 11 is created in the substrate 10A by exposed implantation, i.e., before the bonding of the stiffener which is too thick to be traversed by the implantation such as to define the bulk substrate. The presence of the stiffener facilitates the detachment of the cleaved parts from the substrate 12 by rigidifying the fine layer of the substrate 10A which will be removed with the deposited layer.

In the case where the substrate 10 is composite, a substrate 12 is formed which is also composite and comprises, in reference to FIG. 2C, a support substrate 10C and a source substrate 10E embrittled beforehand so as to define a seed layer 10D. The implantation is performed, before the bonding, by means of the oxide layer 10F which serves for the bonding of the source substrate 10E on the support substrate 10C (In this respect, refer to the detailed description of examples 1 and 2).

First case: The Thermal Budget Provided by the Deposition is Less than the Thermal Budget Necessary for Cleavage.

By deposition, it is understood in this text molecular beam epitaxy (MBE) or the techniques known under the name CVD: LPCVD (“Low Pressure Chemical Vapor Deposition”, PECVD (“Plasma Enhanced Chemical Vapor Deposition”) or even MOCVD (“Metal Organic Chemical Vapor Deposition”).

In the case where the thermal budget provided by the deposition of material is less than the thermal budget of cleavage, the method comprises successively:
the deposition of material on the embrittled substrate: in reference to the FIG. 3A, a layer 21 is deposited on the front face of substrate 12 and a layer 20 on the rear face;
the cleavage of the embrittled substrate (schematically shown, in FIG. 3B, by the thickly dotted lines at the place of the embrittlement zone 11);
detachment of the two parts of the cleaved substrate.

The cleavage is principally performed by the application of a thermal budget but it can be finalized by insertion of a blade or the application of a mechanical pressure.

Second case: The Thermal Budget Provided by the Deposition is Greater than the Thermal Budget Necessary for Cleavage

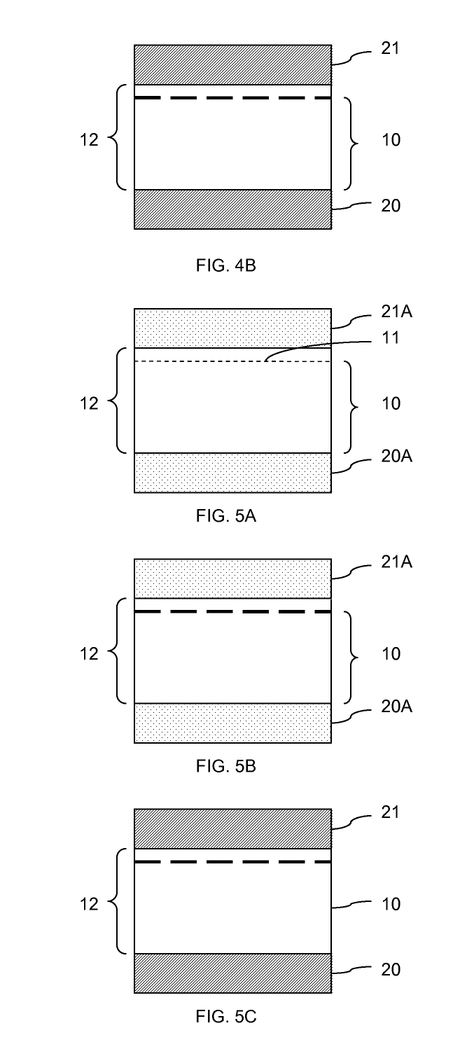

In the case where the thermal budget necessary for cleavage is less than the thermal budget provided by the deposition of the material, two different manners of operation are possible:
A first option is to perform successively the following steps:
realize the cleavage of the embrittled substrate 12 by providing the necessary thermal budget (as schematically illustrated in FIG. 4A);
depositing the material without selection of the face at the temperature adapted to the manner of depositing a layer 21 in the front face and a layer 20 in the rear face (FIG. 4B)
detaching the two parts of the cleaved substrate

One considers in this case that the cleavage takes place during the deposition step; in fact, the ramp of temperature applied in view of the deposition per se, and which provides the thermal budget necessary for cleavage, is considered as being a part of the deposition step.

The cleavage taking place before the deposition of the material, it is in this case desirable to hold the embrittled substrate such that after the fracture, the two cleaved parts do not detach in order to avoid that the material settles in the interstices. In this regard, the substrate 12 is preferably placed horizontally so that, under the weight of the upper part, the two parts stay in contact with each other during the depositing step.

A second option consists of performing the steps in the following order:

depositing the material under amorphous form on the embrittled substrate.

For this purpose, a thermal budget is applied less than the one necessary for cleavage. Referring to FIG. 5A, an amorphous layer 21A is formed in the front face and an amorphous layer 20A in the rear face.
realising the cleavage of the embrittled substrate covered with amorphous material by providing the thermal budget for cleavage (FIG. 5B)
making the deposited material crystalline by augmenting the temperature: in reference to FIG. 5C, the crystalline layers 21 and 20, respectively, in the front face and the rear face of the substrate,
detaching the two parts of the cleaved substrate.

Whatever the order of the steps of deposition and cleavage, the thermal budget provided at the time of the deposition of material contributed to the budget of fracture of the embrittled substrate. Moreover, the operations of deposition and cleavage can be carried out in the same enclosure, by simple adaptation of the ramps of temperature and the thermal budgets applied. This makes it possible to limit the number of steps required to obtain substrate 10 covered with only one layer. However, in the case where the fractured material produces particles which can contaminate the deposition chamber, it is preferable to realize the cleavage outside of the chamber. If the cleavage is realized before depositing, the embrittled substrate 12 will be manipulated so as to keep the cleaved parts in contact until deposition.

Detachment

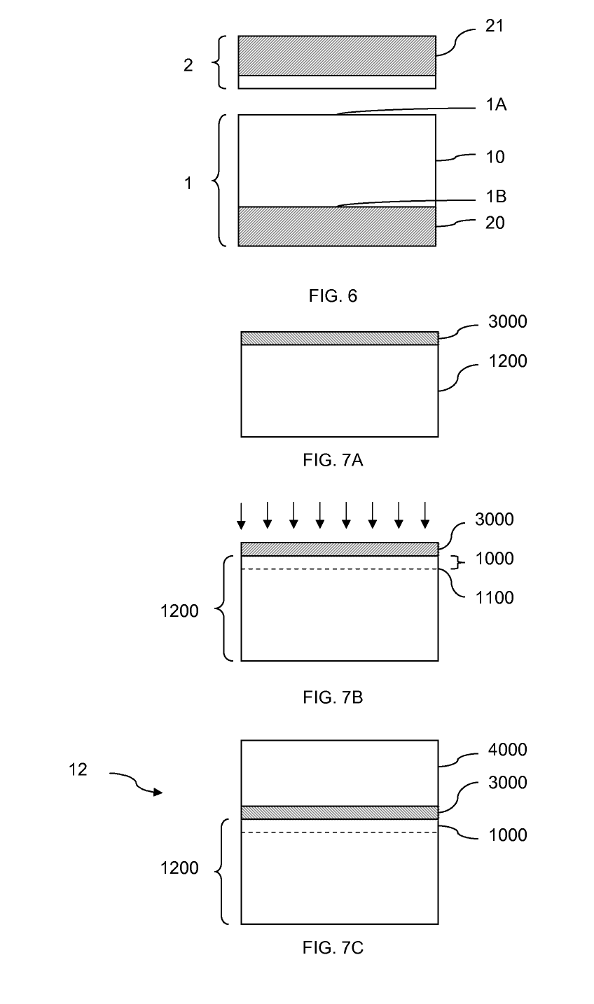

Finally, in all of the cases, the two parts of the cleaved substrate are detached. For this purpose, two tweezers can be used which, with an aspiration system, make it possible to handle the substrate. Referring to FIG. 6, a final structure 1 is obtained, on the one hand, comprising a substrate 10 covered, on the desired face (rear face 1B), of a deposited layer 20 and, on the other hand, a residual structure 2 comprising a remainder of substrate 12 covered by layer 21 deposited on the other face. This residual structure 2 can be eliminated but can also be recycled by eliminating the deposited layer 21 and the polishing of the remainder of the source substrate 12 before reusing it.

Later steps

The front face 1A of the final structure 1, deprived of the deposited layer 21, can subsequently be prepared in view of the later use (for example, a molecular beam epitaxy).

In the case of the manufacture of a composite structure 1, it is preferable to perform a stabilization annealing of this structure intended to strengthen the bonding energy between the different layers.

In the case (cf. FIG. 2C) where the transferred layer 10D not covered is in a material (such as silicon, for example) forming a native oxide in the contact of air, it is necessary to define the depth of the implantation in the source substrate 10E so as to obtain a final thickness of the desired layer 10D by taking into account its partial consumption during the formation of the SiO₂ during the stabilization annealing: the final thickness of the layer 10D transferred after withdrawal of the oxide is slighter from this fact to this than the initial thickness transferred. Likewise, if the material of the deposited layer 20 is in a material forming a native oxide, it is necessary to provide for the thickness which will be consumed by the formation of the oxide and to deposit a greater thickness of the material as a result.

Different examples of the implementation of the method conforming to the invention will now be explained.

### EXAMPLE 1

### Formation of a Rear Layer in p-Si on a Composite Substrate SopSiC

Variant 1: Cleavage is Performed During the Deposition Stage

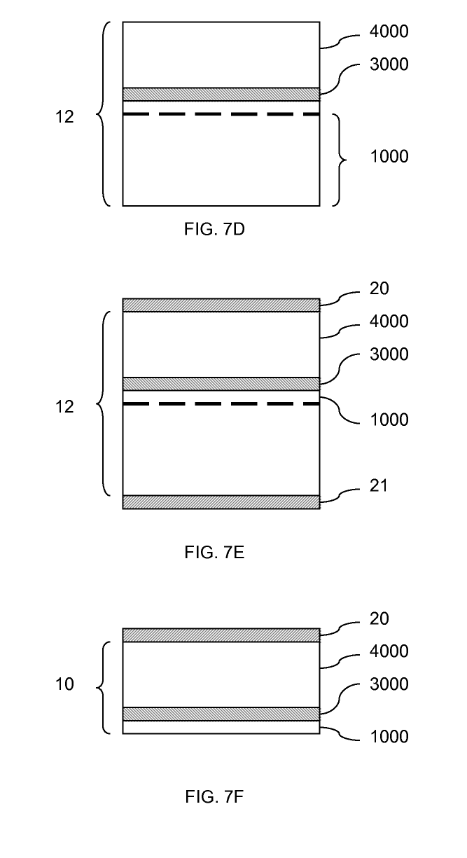

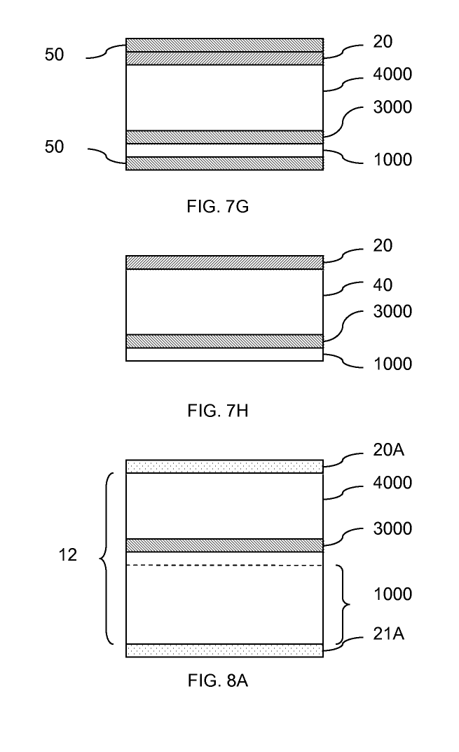

Referring to FIG. 7A, a source substrate 1200 in monocrystalline silicon is oxidized to form a layer 3000 of SiO₂ of about 2000 Å of thickness. Referring to FIG. 7B, a embrittlement zone 1100 is created by implantation in this source substrate 1200 through the layer 3000 so as to define a seed layer 1000. The implantation energy is adapted by the person skilled in the art according to the depth which is desired to be obtained; the dose of implantation is in the region of 5.10^{e}16 atoms/cm². Referring to FIG. 7C, a hydrophilic bonding is performed by putting in contact through layer 3000 of SiO₂ the embrittled source substrate 1200 with a support 4000 in polycrystalline SiC so as to form a embrittled structure 12, the surfaces having been prepared in an adequate manner.

This embrittled structure 12 is placed in a deposition chamber so that the two parts do not move apart from one another after cleavage, then the structure is heated to 350° C. to effect a first stabilization of the bonding between the monocrystalline Si and the p-SiC.

Referring to FIG. 7D, a ramp of temperature intended to lead the temperature from 350° to 620° C. is applied so that the cleavage can take place under 500° C. in the course of the ramp.

Referring to FIG. 7E, one proceeds to the depositing of polycrystalline silicon during 6h30 without selection of the face at 620° C. Thus, two layers 20 and 21 are thereby formed of 5 micrometers thickness on each of the faces of the structure 12.

The temperature is decreased by an appropriate ramp before the opening of the chamber.

Referring to FIG. 7F, the cleaved parts are detached from the structure 12, for example, with the aid of tweezers. The face in monocrystalline silicon of the substrate SopSiC 10 is thus exposed.

Referring to FIG. 7G, a second stabilization annealing is then performed under the atmosphere of water vapour at 900° C. which leads to the formation of a layer 50 of SiO₂ on each of the two faces. The formation of oxide is made by consumption of silicon present on the two faces of the SopSiC substrate and, in particular of monocrystalline silicon deteriorated to the level of the embrittlement zone by the implantation, which contributes to eliminate this zone rich in defects.

Referring to FIG. 7H, the layers 50 of SiO₂ are removed with the aid of a solution of HF, the HF being selective to SiO₂ and not attacking the silicon.

Finally, the surface of monocrystalline silicon of the SopSiC is cleaned to prepare it for a later epitaxy.

The remaining substrate of monocrystalline silicon can be recycled, for example, by a polishing of its two surfaces.

Variant 2: Cleavage is Performed After the Deposition The method commences with the same steps which were described in reference to FIGS. 7A to 7C of the first variant.

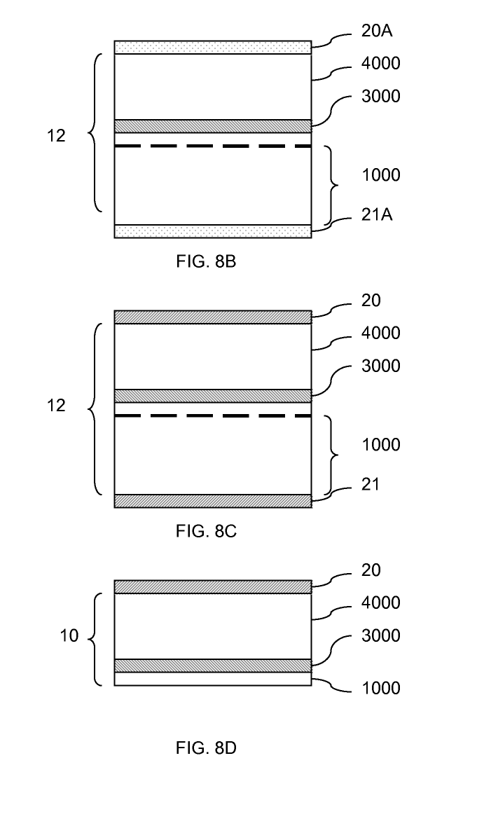

Referring to FIG. 8A, the embrittled substrate is placed in the deposition chamber.

The cleavage being performed after the deposition, the problem of spacing of the cleaved parts is not posed and the substrate can be placed, for example, vertically. The substrate is heated to 350° C. to perform a first stabilization of the adhesive bonding between the monocrystalline silicon and the p-SiC, then depositing silicon in amorphous form at 350° C., so as to form two layers 20A and 21A on each side of the substrate.

Referring to FIG. 8B, a ramp of heating up to 620° C. is applied, which allows the fracture of the substrate 12 according to the embrittlement zone.

Referring to the FIG. 8C, a ramp of temperature up to 620° C. is subsequently performed for crystallising the silicon of the layers 20A and 21A in layers 20 and 21.

Referring to the FIG. 8D, the cleaved parts of the structure are separated outside of the chamber, the front face in monocrystalline silicon of SopSiC 10 being free from deposit.

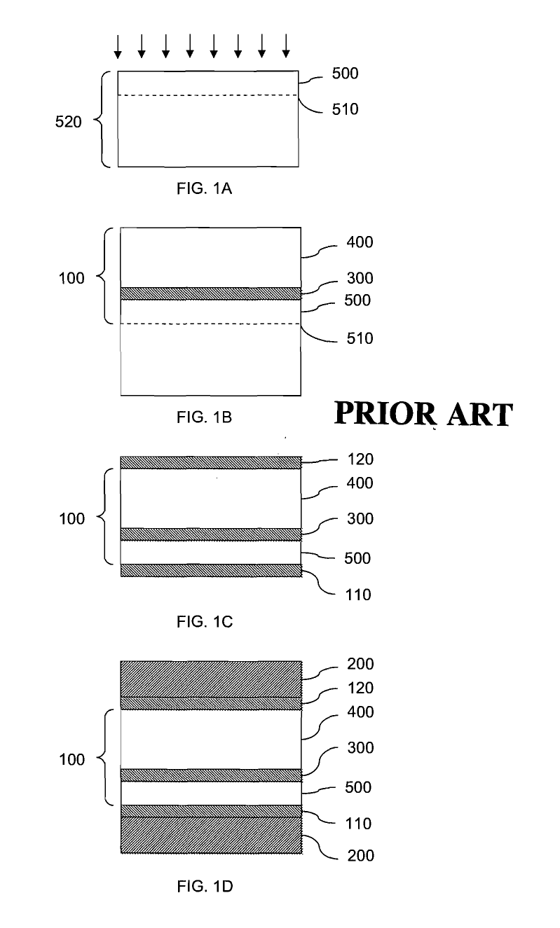

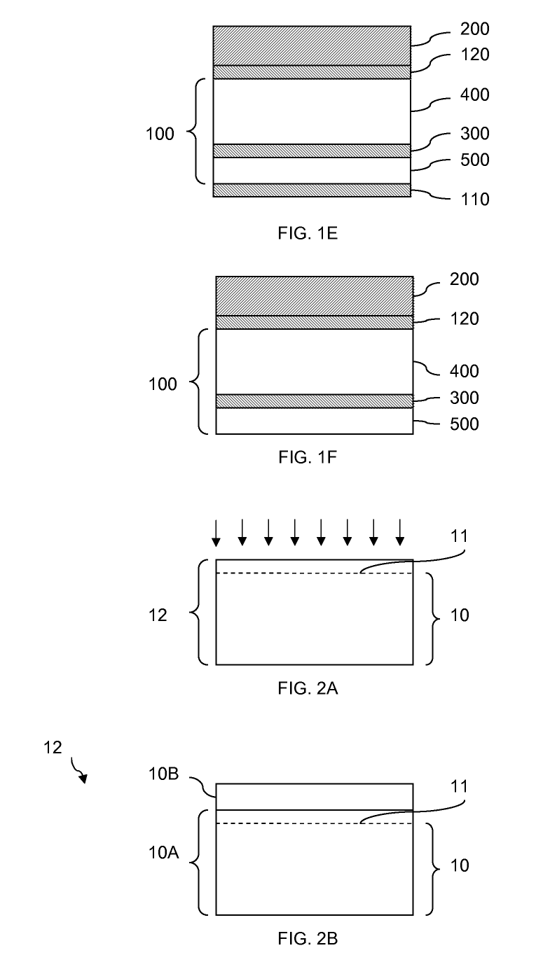

The method is completed with the same steps as those described in reference to FIGS. 7G and 7H of the preceding variant. In the particular example of the formation of a layer in p-Si in the rear face of a substrate SopSiC, the realisation of two variants of which have just been described, the method permits the increasing of efficiency of infrared absorption of SopSiC by means of the rear layer in p-Si since, contrary to the known method described in reference to FIGS. 1A to 1F, there is not any insulating layer of SiO₂ between the substrate SopSiC and the p-Si (cf. layer 120 of FIG. 1F). This advantage can be confirmed in a general manner for the manufacture of all composite substrates in which the support substrate forms a native oxide with air.

In addition, the material to cleave for manufacturing the SopSiC being in silicon, the particles formed during cleavage are in silicon. They do not contaminate the deposition chamber of silicon so that cleavage is advantageously realized in the chamber.

### EXAMPLE 2

### Formation of a Rear Layer in Polycrystalline Si on a Composite substrate SiCopSiC.

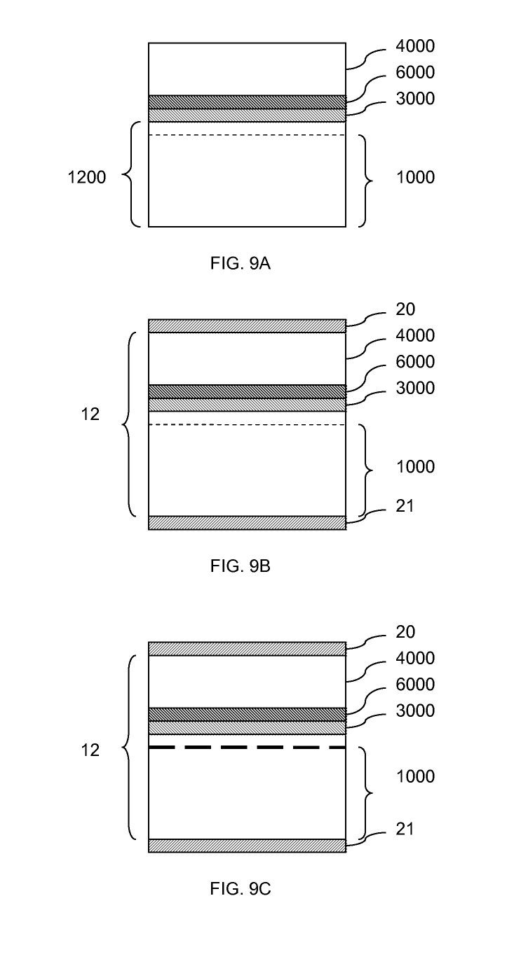

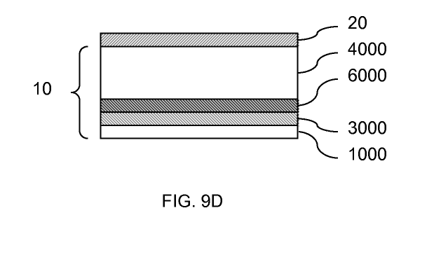

Referring to FIG. 9A, a substrate 1200 in monocrystalline SiC is oxidized, on the one hand, during 2 hours at 1150° C. under oxygen to form a layer 3000 of SiO₂ of 5000 angstroms of thickness.

Then a embrittlement zone 1100 is created in this substrate by implantation through this layer with a dose in the region of 5.10^{e}16 atoms/cm², the energy being parametered by the person of skill in the art according to the depth of the desired implantation.

On the other hand, a layer 6000 of oxide SiO₂ of 5000 Å of thickness is deposited on the front face of a support 4000 in SiC polycrystalline.

Next, the surfaces of the layers of oxide 3000 and 6000 are activated in view of a bonding. For this purpose, a polishing of the oxide 3000 is performed so as to remove 500 Å and to diminish the roughness. Likewise, a polishing of the oxide 6000 is performed to eliminate 2500 Å and smooth its surface. Techniques of polishing are well known to the person of skill in the art; one can implement, in particular, a chemical-mechanical polishing (CMP).

The substrate 1200 in SiC and the support 4000 in p-SiC are bonded thanks to the oxide layers 3000 and 6000, putting in contact the two prepared faces. The structure obtained is illustrated in FIG. 9A.

Referring to FIG. 9B, this embrittled structure 12 is placed in the deposition chamber. The structure 12 can be disposed either vertically or horizontally. A temperature ramp up to 620° C. is applied, then polycrystalline silicon is deposited during 6h30 so as to form two layers 20 and 21 of 5 micrometers of thickness on each face of the structure 12.

Referring to FIG. 9C, one proceeds to a heating to 1000° C. which leads to a cleavage of the substrate 1200 in monocrystalline SiC.

Referring to FIG. 9D, the two cleaved parts are detached outside of the chamber. A substrate 10 (designated SiCopSiC) is thereby obtained, the front face of which, in monocrystalline SiC, is exposed.

The following steps are the same as those described in reference to the FIGS. 7G and 7H of the variant 1 of the first example.

The remainder of the source substrate 1200 of monocrystalline SiC may be recycled by stripping off the deposited silicon (layer 21) and polishing the surface.

### EXAMPLE 3

### Formation of a Rear Layer in Polycrystalline Si on a Bulk Substrate in Monocrystalline SiC

Referring to FIG. 2, an embrittlement zone situated in the vicinity of the surface of a substrate 12 of SiC is created by implantation with a dose in the region of 5.10^{e}16 atoms/cm², and the embrittled substrate is placed in the deposition chamber.

Referring to FIG. 3A, one proceeds to the deposition of polycrystalline Si at a temperature of 620° C., without distinction of face. Two layers 20 and 21 are thereby formed on the embrittled substrate 12.

Referring to FIG. 3B, a ramp of temperature is applied up to 900° C. in order to cleave the substrate 12 along the embrittlement zone 11.

Referring to FIG. 6, the two cleaved parts are separated outside of the deposition chamber, and a substrate 10 is recovered, the face 1B of which, is covered with deposited polycrystalline Si (layer 20), and the other face 1A is exposed and can be prepared in view of a later epitaxy.

1.-15. (canceled)

16. A method for manufacturing an electronic, optic, optoelectronic or photovoltaic structure comprising a substrate having a thin layer on one face thereof, which method comprises:
forming an embrittled substrate having first and second faces and an embrittlement zone therebetween, the embrittlement zone defining the substrate and a remainder;
depositing a thin layer of material on both the first and second faces of the embrittled substrate; and
cleaving the embrittled substrate at the embrittlement zone to obtain the structure having the thin layer of deposited material on one face and one face that is exposed.

17. The method according to claim 16, wherein the cleaving requires the application of a thermal budget that is greater than that provided by the deposition of the thin layer.

18. The method according to claim 17, wherein the thin layer is deposited before the cleaving of the embrittled substrate.

19. The method according to claim 16, wherein the cleaving requires the application of a thermal budget that is less than that provided by the deposition of the thin layer such that the cleaving occurs during the depositing of the thin layer.

20. The method according to claim 19, which further comprises holding the embrittled substrate so that the substrate and remainder do not move apart from each other during the depositing of the thin layer.

21. The method according to claim 20, wherein the embrittled substrate is held horizontally during the depositing of the thin layer.

22. The method according to claim 16, wherein the cleaving is performed in the same chamber used for depositing the thin layer.

23. The method according to claim 16, which further comprises:
depositing material in amorphous form on both faces of the embrittled substrate;
cleaving the embrittled substrate at the embrittlement zone; and
annealing the substrate at a temperature suitable to crystallize the amorphous material to form the thin layer.

24. The method according to claim 16, wherein the embrittled substrate is formed by implanting ionic species in a semiconductor substrate to form the embrittlement zone therein.

25. The method according to claim 16, wherein the substrate is a composite substrate comprising a support substrate and a seed layer to facilitate depositing of the thin layer.

26. The method according to claim 16, wherein the substrate comprises Al₂O₃, ZnO, a group III/V material or their ternary and quaternary alloys, Si, SiC, polycrystalline SiC, diamond, or Ge and its alloys.

27. The method according to claim 16, wherein the material deposited to form the thin layer is amorphous Si, monocrystalline Si, polycrystalline Si, Ge, SiC, polycrystalline SiC, amorphous SiC, a group III/V material or their ternary and quaternary alloys, Al₂O₃, SiO₂, Si₃N₄ or diamond.

28. The method according to claim 16, wherein the substrate is a composite structure of SopSiC or SiCopSiC and the thin layer of deposited material is polycrystalline silicon.

29. The method according to claim 16, which further comprises conducting molecular beam epitaxy on the exposed face of the substrate of the structure.
